(19) United States
(12) Patent Application Publication
(10) Pub. No.: US 2026/0244109 A1
(43) Pub. Date: Aug. 20, 2026

(54) SURFACE PLASMON LITHOGRAPHY METHOD

(71) Applicant: INSTITUTE OF MICROELECTRONICS, CHINESE ACADEMY OF SCIENCES, Beijing (CN)

(72) Inventors: Jianfang He, Beijing (CN); Yayi Wei, Beijing (CN); Huwen Ding, Beijing (CN); Yajuan Su, Beijing (CN)

(21) Appl. No.: 19/374,652

(22) Filed: Oct. 30, 2025

(30) Foreign Application Priority Data
Feb. 20, 2025 (CN) 202510190177.0

(51) Int. Cl. G03F 7/00; G02B 1/00

(52) U.S. Cl. CPC G03F 7/70375; G03F 7/70325; G03F 7/70625; G02B 1/002

(57) ABSTRACT

A surface plasmon lithography method is provided according to the present disclosure, relating to the field of semiconductor manufacturing. In the method, an inner radius and an arrangement mode of a target pattern is determined based on a target imaging pattern, where the target pattern is a periodically-arranged circular pattern formed by projection of a mask absorption layer on a surface of a substrate in a multilayer metasurface superlens; a TM-polarized light with a wavelength of 365 nm is used as an incident light; and the incident light is vertically irradiated on a substrate with the target pattern of a target multilayer metasurface superlens to form the target imaging pattern on a mask layer of a to-be-lithographed structure.

The present application claims the priority to Chinese Patent Application No. 202510190177.0, titled “SURFACE PLASMON LITHOGRAPHY METHOD,” filed on Feb. 20, 2025 with the Chinese Patent Office, which is incorporated herein by reference in its entirety.

### FIELD

The present disclosure relates to the technical field of semiconductor manufacturing, and in particular to a surface plasmon lithography method.

### BACKGROUND

With the decreasing size of nodes in integrated circuit process, how to achieve imaging of fine structures in large-scale integrated circuit processes gains attracts attention.

Surface Plasmon Lithography (SPL) technology is a lithography technology according to which high-resolution patterning is performed based on Surface Plasmon Polaritons (SPPs). With the surface plasmon lithography technology, specially designed metal films are coupled for transmitting evanescent waves, thereby achieving imaging of fine structures of objects with feature sizes far smaller than a wavelength scale. In the integrated circuit process, it is required to perform complex computation simulations and experimental verifications in advance and design a corresponding multilayer metasurface superlens for forming specific patterns using the surface plasmon lithography technology. The cost for designing the multilayer metasurface superlens is high.

Therefore, how to achieve imaging of specific patterns in integrated circuit processes by using a multilayer metasurface superlens at a low cost is an issue to be solved.

### SUMMARY

To solve the above issue, a surface plasmon lithography method is provided according to the present disclosure, to achieve imaging of specific patterns in integrated circuit processes by using a multilayer metasurface superlens at a low cost.

The following technical solutions are provided according to the embodiments of the present disclosure.

A surface plasmon lithography method is provided according to the present disclosure. The method includes: determining, based on a target imaging pattern, an inner radius and an arrangement mode of a target pattern, where the target pattern is a periodically-arranged circular pattern formed by projection of a mask absorption layer of a multilayer metasurface superlens on a surface of a substrate of the multilayer metasurface superlens; using a TM (Transverse Magnetic)-polarized light with a wavelength of 365 nm as an incident light; and vertically irradiating the incident light on a substrate with the target pattern of a target multilayer metasurface superlens to form the target imaging pattern on a mask layer of a to-be-lithographed structure, where the multilayer metasurface superlens includes the substrate, the mask absorption layer, a filling layer, a first metal-dielectric composite film and a second metal-dielectric composite film stacked sequentially, the to-be-lithographed structure includes a wafer, a metal reflecting layer and the mask layer stacked sequentially, and the mask layer is arranged close to the second metal-dielectric composite film in the target multilayer metasurface superlens.

In an embodiment, the determining, based on a target imaging pattern, an inner radius and an arrangement mode of a target pattern includes: determining the inner radius of the target pattern as a first size and determining the arrangement mode as a dense arrangement mode in a case that the target imaging pattern is in a line shape, where the first size is greater than a half of an outer radius of the target pattern.

In an embodiment, the determining, based on a target imaging pattern, an inner radius and an arrangement mode of a target pattern includes: determining the inner radius of the target pattern as a first size and determining the arrangement mode as an interlacing arrangement mode with an outer diameter of the target pattern as a period in a case that the tar get imaging pattern is in a circle shape, where the first size is greater than a half of the outer radius of the target pattern.

In an embodiment, the mask layer of the to-be-lithographed structure is a negative photoresist layer.

In an embodiment, the outer radius of the target pattern is 65 nm, and the first size for the inner radius of the target pattern is 50 nm.

In an embodiment, the determining, based on a target imaging pattern, an inner radius and an arrangement mode of a target pattern includes: determining the inner radius of the target pattern as a second size and determining the arrangement mode as interlacing arrangement mode with an outer diameter of the target pattern as a period in a case that the target imaging pattern is in a square shape, where the second size is less than a half of the outer radius of the target pattern.

In an embodiment, the mask layer of the to-be-lithographed structure is a positive photoresist layer.

In an embodiment, the outer radius of the target pattern is 65 nm, and the second size for the inner radius of the target pattern is 30 nm.

In an embodiment, the mask absorption layer of the target multilayer metasurface superlens is a chromium layer.

In an embodiment, a thickness of the mask absorption layer of the target multilayer metasurface superlens is similar to a thickness of the filling layer of the target multilayer metasurface superlens.

Compared with the conventional technology, the present disclosure has the following beneficial effects.

In the embodiments of the present disclosure, an inner radius and an arrangement mode of a target pattern is determined based on a target imaging pattern, where the target pattern is a periodically-arranged circular pattern formed by projection of a mask absorption layer on a surface of a substrate in a multilayer metasurface superlens. A TM-polarized light with a wavelength of 365 nm is used as an incident light. The incident light is vertically irradiated on a substrate with the target pattern of a target multilayer metasurface superlens to form the target imaging pattern on a mask layer of a to-be-lithographed structure, where the multilayer metasurface superlens includes the substrate, the mask absorption layer, a filling layer, a first metal-dielectric composite film and a second metal-dielectric composite film stacked sequentially, the to-be-lithographed structure includes a wafer, a metal reflecting layer and the mask layer stacked sequentially, and the mask layer is arranged close to the second metal-dielectric composite film in the target multilayer metasurface superlens. Therefore, the formed imaging pattern can be regulated by only changing the inner radius and the arrangement mode of the target pattern, that is, changing the inner radius and the arrangement mode of the circular pattern formed by projection of the mask absorption layer on the substrate in the multilayer metasurface superlens. Due to the low cost for designing the mask absorption layer in the multilayer metasurface superlens, imaging of specific patterns in integrated circuit processes by using the multilayer metasurface superlens can be achieved at a low cost.

### BRIEF DESCRIPTION OF THE DRAWINGS

For clearly illustrating the technical solutions in the embodiments of the present disclosure or in the conventional technology, drawings used in the embodiments or the conventional technology are briefly described hereinafter. Apparently, the following drawings are only used in some embodiments of the present disclosure, and those skilled in the art can obtain other drawings based on these drawings without any creative efforts.

FIG. 1 is a schematic structural diagram of a multilayer metasurface superlens according to an embodiment of the present disclosure;

FIG. 2 is a schematic diagram of a to-be-lithographed structure according to an embodiment of the present disclosure;

FIG. 3 is a flowchart of a surface plasmon lithography method according to an embodiment of the present disclosure;

FIG. 4 is a schematic diagram of a target pattern according to an embodiment of the present disclosure;

FIG. 5 is a two-dimensional heat map of light intensity distribution of imaging on an x-y plane of a film layer according to an embodiment of the present disclosure;

FIG. 6 is a schematic diagram of a target pattern according to another embodiment of the present disclosure;

FIG. 7 is a two-dimensional heat map of light intensity distribution of imaging on an x-y plane of a film layer according to another embodiment of the present disclosure;

FIG. 8 is a schematic diagram of a target pattern according to another embodiment of the present disclosure; and

FIG. 9 is a two-dimensional heat map of light intensity distribution of imaging on an x-y plane of a film layer according to another embodiment of the present disclosure.

### DETAILED DESCRIPTION

The surface plasmon lithography method and the multilayer metasurface superlens according to the present disclosure are applied to the field of semiconductor manufacturing, which is merely exemplary and does not limit the application fields of the surface plasmon lithography method and the multilayer metasurface superlens according to the present disclosure.

In the specification, the claims and the drawings of the present disclosure, terms such as “first”, “second”, “third”, and “fourth” are intended to distinguish between different objects and not to limit a specific order.

In the embodiments of the present disclosure, words such as “as an example” or “for example” are used for describing an example, an illustration, or an explanation. Any embodiments or design solutions described as “as an example” or “for example” in the embodiments of the present disclosure should not be interpreted as preferable or advantageous over other embodiments or design solutions. Specifically, the words such as “as an example” or “for example” are intended to present relevant concepts in a specific manner.

The terms in the embodiments of the present disclosure are only used for explaining the embodiments of the present disclosure, rather than limiting the present disclosure.

In order to enable those skilled in the art to better understand the technical solution according to the present disclosure, the technical solutions according to the embodiments of the present disclosure are described clearly and completely hereinafter with reference to the drawings in the embodiments of the present disclosure. Apparently, the described embodiments are only part of the embodiments according to the present disclosure, rather than all of the embodiments. Based on the embodiments of the present disclosure, all other embodiments obtained by those skilled in the art without any creative effort fall within the protection scope of the present disclosure.

Multilayer metasurface superlens is an optical component designed based on the concept of metamaterials. For a multilayer metasurface superlens, light waves are manipulated based on nanoscale structures, precisely controlling the features such as phase, amplitude, and polarization of the light. The multilayer metasurface superlens may achieve a higher resolution than the conventional optical lenses, surpassing the conventional diffraction limit.

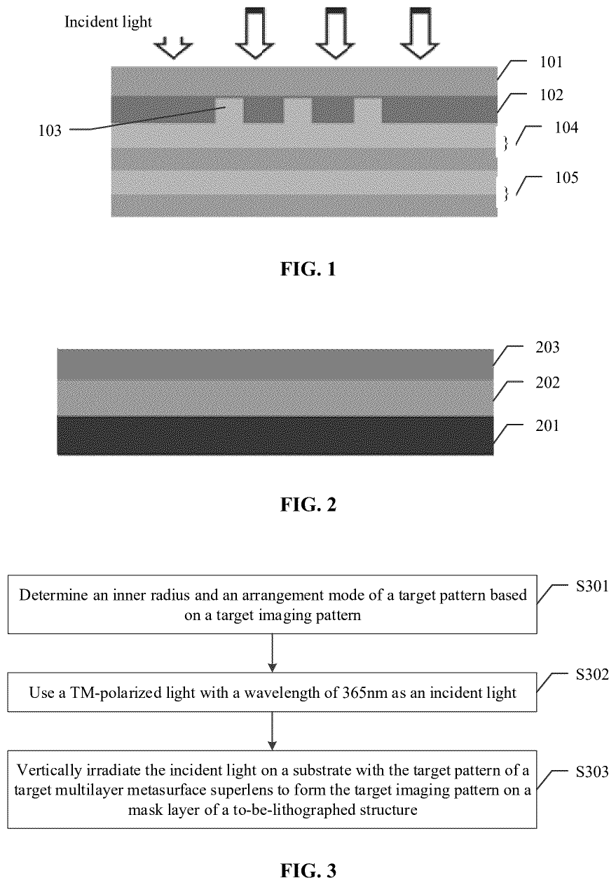

Referring to FIG. 1, FIG. 1 is a schematic structural diagram of a multilayer metasurface superlens according to an embodiment of the present disclosure. The multilayer metasurface superlens includes: a substrate 101, a mask absorption layer 102, a filler layer 103, a first metal-dielectric composite film 104, and a second metal-dielectric composite film 105.

The substrate 101, the mask absorption layer 102, the filling layer 103, the first metal-dielectric composite film 104, and the second metal-dielectric composite film 105 are stacked sequentially. The mask absorption layer 102 and the filling layer 103 are arranged in contact with a dielectric side of the first metal-dielectric composite film 104. The material of the substrate 101 may be silicon dioxide (SiO₂).

The thickness of mask absorption layer 102 is similar to the thickness of the filling layer 103. The filling layer 103 is arranged to fill gaps in the pattern formed by the mask absorption layer 102, reducing optical interference caused by uneven surfaces.

The material of the metal layer in the first metal-dielectric composite film 104 and the material of the metal layer in the second metal-dielectric composite film 105 are an identical metal, such as silver (Ag). The material of the dielectric layer in the first metal-dielectric composite film 104 and the material of the dielectric layer in the second metal-dielectric composite film 105 are an identical metal, such as titanium dioxide (TiO₂). That is, both the first metal-dielectric composite film 104 and the second metal-dielectric composite film 105 are Ag/TiO₂ composite films. Each of the metal layers may have a thickness of 10 nm, and each of the dielectric layers may have a thickness of 20 nm.

The projection of the mask absorption layer 102 on the substrate 101 is a periodically-arranged circular pattern.

In an embodiment, the material of the mask absorption layer 102 may be configured as chromium (Cr), the thickness of the mask absorption layer 102 may be configured to 40 nm, and the sidewall angle of the mask absorption layer 102 may be configured to 0°, to clearly define the edges of the pattern and facilitate high-precision lithography. The material of the filling layer 103 is TiO₂ material that matches the real part of the dielectric constant of Ag, and the thickness of the filling layer 103 is 40 nm.

Hyperbolic metamaterials (HMMs) are artificially designed composite structure which a dielectric constant is positive in a direction and negative in another direction, having an isofrequency profile with a hyperbolic shape. Due to the specific dielectric property of the hyperbolic metamaterials, the hyperbolic metamaterials may support anomalous electromagnetic modes at sub wavelength scales, such as extremely high effective refractive indices or negative refractive phenomena.

In the embodiments of the present disclosure, the first metal-dielectric composite film 104 and the second metal-dielectric composite film 105 are stacked. By alternately stacking the metal layers and the dielectric layers, a multi-layer structure with an anisotropic dielectric constant is constructed, thereby forming a hyperbolic metamaterial.

When an incident light is irradiated on HMMs formed by the first metal-dielectric composite film 104 and the second metal-dielectric composite film 105, surface plasmons may be excited. These surface plasmons may propagate inside the material and undergo negative refraction at specific locations, simulating effects of materials with negative refractive index, compensating for losses of evanescent waves, reconstructing high-resolution images. Therefore, light is focused on extremely small points, achieving a nanoscale resolution.

Referring to FIG. 2, FIG. 2 is a schematic diagram of to-be-lithographed structure according to an embodiment of the present disclosure.

The to-be-lithographed structure includes at least a wafer 201, a metal reflecting layer 202, and a mask layer 203 stacked sequentially. The mask layer 203 is arranged close to the second metal-dielectric composite film 105 of the multilayer metasurface superlens according to the above embodiments.

In an embodiment, the material of the metal reflecting layer 202 is the same as the material of the metal layer in the first metal-dielectric composite film 104 and the material of the metal layer in the second metal-dielectric composite film 105. For example, the material may be silver. The thickness of the metal reflecting layer 202 may be 40 nm.

In an embodiment, the mask layer 203 may be a photoresist layer with a thickness of 20 nm. A positive photoresist or a negative photoresist may be selected based on a target imaging pattern and a corresponding target multilayer metasurface superlens.

As an example, the metal reflecting layer 202 may be deposited on a surface of the wafer 201, then a photoresist may be coated on the surface of the metal reflecting layer 202 to obtain the mask layer 203, thereby obtaining a to-be-lithographed structure. The multilayer metasurface superlens is placed above the mask layer 203, and the angle and intensity of the incident light are adjusted to irradiate the incident light on the multilayer metasurface superlens and excite surface plasmons. The surface plasmons propagate inside the multilayer metasurface superlens and undergo negative refraction at specific locations, and light is focused at positions on the mask layer, thereby forming a high-resolution target imaging pattern on the mask layer of the to-be-lithographed structure.

Referring to FIG. 3, FIG. 3 is a flowchart of a surface plasmon lithography method according to an embodiment of the present disclosure. The method includes the following steps S301 to S303.

In step S301, an inner radius and an arrangement mode of a target pattern are determined based on a target imaging pattern.

The target pattern is a periodically-arranged circular pattern formed by projection of the mask absorption layer 102 on the surface of the substrate 101 in the multilayer metasurface superlens.

Using a software tool FDTD Solutions, a model may be constructed and an optical behavior of light in the multilayer metasurface superlens according to the embodiments of the present disclosure may be simulated. Based on the simulation, an electric field intensity of a spatial image at a center position of the mask layer in the to-be-lithographed structure may be calculated after processing with the surface plasmon lithography technology, and then the imaging quality may be evaluated. In the embodiments of the present disclosure, to simplify a computational model and ignore a finite-size effect in a y direction, it may be assumed that all components in the y direction are infinitely large.

By changing the inner radius and the arrangement mode of the circular pattern (that is, the target pattern) formed by the projection of the mask absorption layer 102 on the surface of the substrate 101 in the multilayer metasurface superlens, various target imaging patterns with basic shapes commonly used in integrated circuit processes can be obtained. With the software tool, the inner radius and the arrangement mode of the target pattern may be regulated to obtain imaging effects corresponding to target patterns with different inner radius and arrangement modes. With the software tool, a corresponding relationship between imaging effects and inner radius and arrangement modes of the target pattern may be obtained. Thus, based on a target imaging pattern, a multilayer metasurface superlens corresponding to an inner radius and an arrangement mode of a target pattern may be selected according to the obtained corresponding relationship, thereby forming the target imaging pattern on the mask layer of the to-be-lithographed structure.

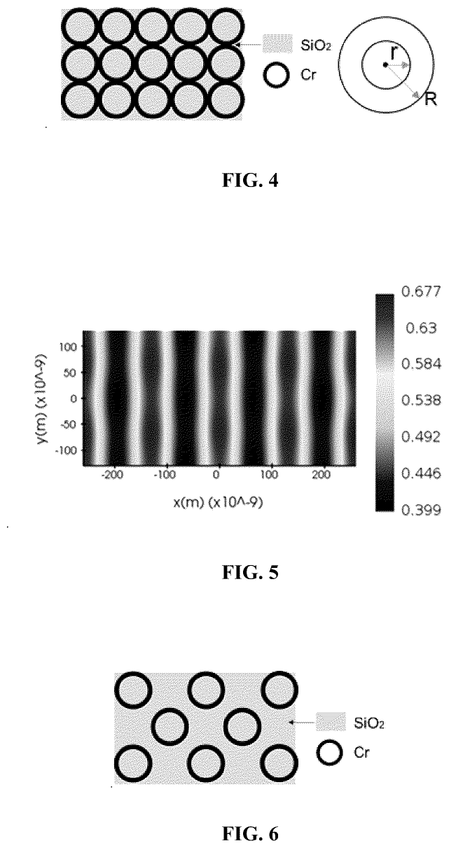

As an example, in a case that the target imaging pattern is in a liner one-dimensional line shape, the inner radius r of the target pattern is determined as a first size and the arrangement mode is determined as a dense arrangement mode, as shown in FIG. 4. In FIG. 4, the first size is greater than a half of an outer radius of the target pattern. In this case, the material of the mask layer in the to-be-lithographed structure may be negative photoresist.

As another example, in a case that the target imaging pattern is in a circular (including elliptical) shape in a liner two-dimensional hole structure, the inner radius r of the target pattern is determined as a first size, and the arrangement mode is determined as an interlacing arrangement mode with an outer diameter of the target pattern as a period, as shown in FIG. 6. In FIG. 6, the first size is greater than a half of the outer radius of the target pattern. In this case, the material of the mask layer in the to-be-lithographed structure may be negative photoresist.

In an embodiment, the outer radius R of the target pattern is 65 nm, and the first size r for the inner radius of the target pattern is 50 nm.

As another example, in a case that the target imaging pattern is in a square shape in a liner two-dimensional hole structure, the inner radius r of the target pattern is determined as a second size, and the arrangement mode is determined as an interlacing arrangement mode with an outer diameter of the target pattern as a period, as shown in FIG. 8. In FIG. 8, the second size is less than a half of the outer radius of the target pattern. In this case, the material of the mask layer in the to-be-lithographed structure may be positive photoresist.

In an embodiment, the outer radius R of the target pattern is 65 nm, and the second size r for the inner radius of the target pattern is 30 nm.

In step S302, a TM-polarized light with a wavelength of 365 nm is used as an incident light.

An electric field in a TM (Transverse Magnetic) mode includes a component parallel to a metal surface, which is exactly a condition required to excite surface plasmon polaritons (SPPs). Therefore, at a metal-dielectric interface, the TM-polarized light may easily excite surface plasmon polaritons, thereby improving the efficiency of exciting the surface plasmon polaritons, enhancing related nonliclose to optical effects, and achieving high resolution.

In addition, based on a Rayleigh rule, a minimum feature size of lithography is proportional to a wavelength of a light source. Therefore, an incident light with a wavelength of 365 nm is used, further improving the lithographic resolution and achieving fine patterning. Furthermore, an ultraviolet light with a wavelength of 365 nm is commonly used in lithography processes, with mature optical components and technologies and suitable for various photoresists. Using the incident light with a wavelength of 365 nm has technical and cost advantages.

In step S303, the incident light is vertically irradiated on a substrate with the target pattern of a target multilayer metasurface superlens to form the target imaging pattern on a mask layer of a to-be-lithographed structure.

The incident light passes through the target multilayer metasurface superlens, and surface plasmon waves are excited on the surface of the metal-dielectric composite films in the target multilayer metasurface superlens. The surface plasmon waves propagate on the surface of the metal-dielectric composite films and are controlled by the target multilayer metasurface superlens to form the target imaging pattern. The mask layer 203 in the to-be-lithographed structure is arranged close to the second metal-dielectric composite film 105 in the target multilayer metasurface superlens.

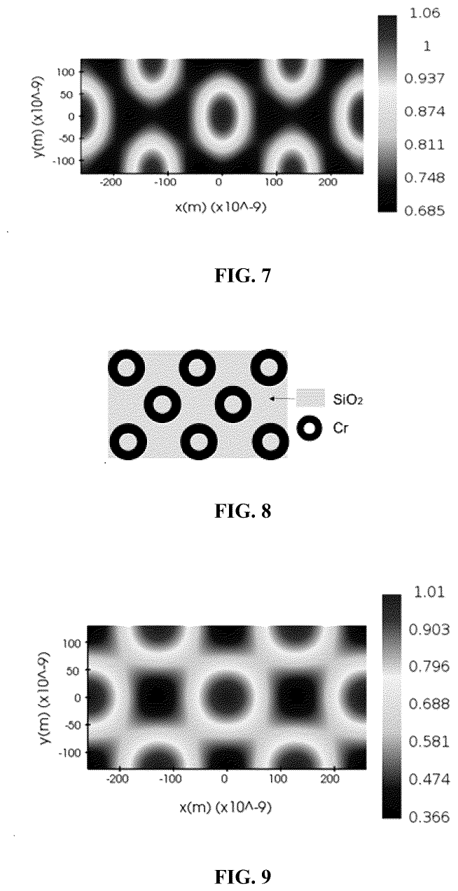

Referring to FIG. 5, FIG. 7 and FIG. 9, FIG. 5, FIG. 7 and FIG. 9 show two-dimensional heat maps of light intensity distribution of imaging on an x-y plane of a mask layer. In FIG. 5, FIG. 7 and FIG. 9, the horizontal axis and the vertical axis represent positions, the light intensity distribution at different positions in the mask layer is represented by changes in color, and blue represents a low light intensity and red represents a high light intensity with reference to a color scale on the right.

As an example, in the target multilayer metasurface superlens, in the case that the inner radius of the target pattern is the first size and the arrangement mode is the dense arrangement mode, the target imaging pattern formed on the mask layer of the to-be-lithographed structure is shown in FIG. 5. The target imaging pattern obtained after development is in a line shape.

As another example, in the target multilayer metasurface superlens, in the case that the inner radius of the target pattern is the first size and the arrangement mode is the interlacing arrangement mode with the outer diameter of the target pattern as the period, the target imaging pattern formed on the mask layer of the to-be-lithographed structure is shown in FIG. 7. The mask layer of the to-be-lithographed structure is a negative photoresist, and the target imaging pattern obtained after development is in a circle shape.

As another example, in the target multilayer metasurface superlens, in the case that the inner radius of the target pattern is the second size and the arrangement mode is the interlacing arrangement mode with the outer diameter of the target pattern as the period, the target imaging pattern formed on the mask layer of the to-be-lithographed structure is shown in FIG. 9. The mask layer of the to-be-lithographed structure is a positive photoresist layer, and the target imaging pattern obtained after development is in a square shape.

In the embodiments of the present disclosure, an inner radius and an arrangement mode of a target pattern is determined based on a target imaging pattern, a TM-polarized light with a wavelength of 365 nm is used as an incident light, and the incident light is vertically irradiated on a substrate with the target pattern of a target multilayer metasurface superlens to form the target imaging pattern on a mask layer of a to-be-lithographed structure. Therefore, the formed imaging pattern can be regulated by only changing the inner radius and the arrangement mode of the target pattern, that is, changing the inner radius and the arrangement mode of the circular pattern formed by projection of the mask absorption layer on the substrate in the multilayer metasurface superlens. Due to the low cost for designing the mask absorption layer in the multilayer metasurface superlens, imaging of specific patterns in integrated circuit processes by using the multilayer metasurface superlens can be achieved at a low cost.

Further, a lithography device is provided according to an embodiment of the present disclosure. The lithography device includes a memory and a processor.

The memory is configured to store program codes and transmit the program codes to the processor.

The processor is configured to execute the program codes to perform the surface plasmon lithography method described above.

It should be noted that embodiments in this specification are described in a progressive way, the same and similar parts among the embodiments may refer to each other, and each of the embodiments emphasize differences from other embodiments. In particular, the description of the apparatus embodiment is simple because it is similar to the method embodiment and the method embodiment may be referred to for better understanding of the apparatus embodiment. The apparatus embodiment described above is only exemplary, in which the units described as separate components may be or not be separated physically, components shown as units may be or not be physical units, that is, the components may be located at one place or distributed as multiple network units. Some or all of the modules may be adopted as needed to achieve the object of the solutions of the embodiments. Those skilled in the art may understand and implement the solution without any creative effort.

The above description is only a specific embodiment of the present disclosure, and the protection scope of the present disclosure is not limited thereto. Any changes or replacements that may be easily conceived by those skilled in the art within the technical scope disclosed in the present disclosure should fall within the protection scope of the present disclosure. Hence, the protection scope of the present disclosure should be defined by the protection scope of the claims.

1. A surface plasmon lithography method, comprising:
determining, based on a target imaging pattern, an inner radius and an arrangement mode of a target pattern, wherein the target pattern is a periodically-arranged circular pattern formed by projection of a mask absorption layer on a surface of a substrate in a multilayer metasurface superlens;
using a TM (Transverse Magnetic)-polarized light with a wavelength of 365 nm as an incident light; and
vertically irradiating the incident light on a substrate with the target pattern of a target multilayer metasurface superlens to form the target imaging pattern on a mask layer of a to-be-lithographed structure, wherein the multilayer metasurface superlens comprises the substrate, the mask absorption layer, a filling layer, a first metal-dielectric composite film and a second metal-dielectric composite film stacked sequentially, the to-be-lithographed structure comprises a wafer, a metal reflecting layer and the mask layer stacked sequentially, and the mask layer is arranged close to the second metal-dielectric composite film in the target multilayer metasurface superlens.

2. The surface plasmon lithography method according to claim 1, wherein the determining, based on a target imaging pattern, an inner radius and an arrangement mode of a target pattern comprises:
determining the inner radius of the target pattern as a first size and determining the arrangement mode as a dense arrangement mode in a case that the target imaging pattern is in a line shape, wherein the first size is greater than a half of an outer radius of the target pattern.

3. The surface plasmon lithography method according to claim 1, wherein the determining, based on a target imaging pattern, an inner radius and an arrangement mode of a target pattern comprises:
determining the inner radius of the target pattern as a first size and determining the arrangement mode as an interlacing arrangement mode with an outer diameter of the target pattern as a period in a case that the target imaging pattern is in a circle shape, wherein the first size is greater than a half of the outer radius of the target pattern.

4. The surface plasmon lithography method according to claim 3, wherein the mask layer of the to-be-lithographed structure is a negative photoresist layer.

5. The surface plasmon lithography method according to claim 2, wherein the outer radius of the target pattern is 65 nm, and the first size for the inner radius of the target pattern is 50 nm.

6. The surface plasmon lithography method according to claim 1, wherein the determining, based on a target imaging pattern, an inner radius and an arrangement mode of a target pattern comprises:
determining the inner radius of the target pattern as a second size and determining the arrangement mode as interlacing arrangement mode with an outer diameter of the target pattern as a period in a case that the target imaging pattern is in a square shape, wherein the second size is less than a half of the outer radius of the target pattern.

7. The surface plasmon lithography method according to claim 6, wherein the mask layer of the to-be-lithographed structure is a positive photoresist layer.

8. The surface plasmon lithography method according to claim 6, wherein the outer radius of the target pattern is 65 nm, and the second size for the inner radius of the target pattern is 30 nm.

9. The surface plasmon lithography method according to claim 1, wherein the mask absorption layer of the target multilayer metasurface superlens is a chromium layer.

10. The surface plasmon lithography method according to claim 1, wherein a thickness of the mask absorption layer of the target multilayer metasurface superlens is similar to a thickness of the filling layer of the target multilayer metasurface superlens.

11. The surface plasmon lithography method according to claim 3, wherein the outer radius of the target pattern is 65 nm, and the first size for the inner radius of the target pattern is 50 nm.
